(19) United States
(12) Patent Application Publication
(10) Pub. No.: US 2004/0188265 A1
(43) Pub. Date: Sep. 30, 2004

(54) Methods for reducing protrusions and within die thickness variations on plated thin film

(76) Inventors: Yang Cao, Beaverton, OR (US); Vinay B. Chikarmane, Portland, OR (US); Rajiv Rastogi, Portland, OR (US); Daniel J. Zierath, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/397,106

(22) Filed: Mar. 25, 2003

(51) Int. Cl. C25D 5/02; C25D 21/12; H01L 21/76

(52) U.S. Cl. 205/170; 205/121; 205/82; 438/400

(57) ABSTRACT

Embodiments of the invention provide methods for electroplating a substrate that substantially reduce or eliminate protrusions and decrease WID thickness variations. The number of protrusions formed on the plating surface is highly dependent upon the electroplating current density. Embodiments of the invention vary the electroplating current waveform by implementing an initial current step sufficient to fill substrate features and a terminal current step sufficient to achieve the specified plating thickness while suppressing protrusions and within die thickness variations.

### FIELD

Embodiments of the invention relate generally to electroplating integrated circuit substrates and, more particularly, methods for reducing protrusions and within die thickness variations on plated thin film.

### BACKGROUND

During the manufacture of integrated circuits, a semiconductor wafer is deposited with a conductive metal to provide interconnects between the integrated components. Aluminum deposition may be used for this purpose. Copper has recently been found to offer distinct advantages over aluminum as a conductive plating for an integrated circuit substrate. Copper is more conductive than aluminum and can be plated into much smaller features (e.g., trenches and vias) having high aspect ratios. This is an important advantage given the trend toward smaller features. Moreover, the deposition process for aluminum is more costly and complex, requiring thermal processing within a vacuum, whereas electroplating can be used to effect copper plating of semiconductor wafers.

The use of copper plating, however, is not without drawbacks. Two significant drawbacks are defects in the copper plating and within die thickness variation of the copper plating.

### Defects

During electroplating and subsequent processing, a variety of critical (killer) and non-critical defects can be developed. Critical defects include, for example, the copper plating being scraped by contaminant particles introduced during handling or impurities in the electroplating bath. During the chemical/mechanical planarization process, which includes polishing, particles on the copper plating may scrape or deform the surface. If such scrapes or deformities are substantial, they can damage the die underneath and eventually impact final yield.

Another example of a critical defect is a crater in the copper plating caused by a corrosive solution used in the fabrication process. During processing, the edge of a plated wafer is typically etched to allow mechanical handling. Etching is accomplished through use of a corrosive solution that may inadvertently splash onto the region where copper etching is absolutely not desired. The unplated area of the wafer will be destroyed in subsequent processing.

Substrates having critical defects in their copper plating will be discarded, while processing continues for substrates with non-critical defects. It is important to be able to determine the critical defect density because critical defects can have a tremendous impact on yield rates, so critical defects must be identified. This is done by reviewing the plated surface with a scanning electron microscope (SEM). Typically, the non-critical defects outnumber the critical defects, and the vast number of non-critical defects make it very difficult to identify the critical defects.

The most prevalent type of non-critical defect is known as a copper protrusion, which is a copper bump, typically 20-50 nm in diameter and 50-500 nm in length, extending from the plating surface. The overwhelming number of copper protrusions renders a 100% SEM review prohibitive, but a representative review is error-prone.

### Within Die Thickness Variations

The other substantial drawback of copper plating is WID thickness variation. Prior to plating, the semiconductor wafer is patterned with vias and trenches that form the interconnects. With typical conformal electroplating, the electroplate metal will grow at a similar rate over the entire surface being plated. If the surface is not flat, the metal will follow the contours of the surface. Conformal electroplating is not suitable for surfaces having small features, as it tends to leave a seam or hole inside the feature at the end of the plating. FIG. 1A illustrates the drawbacks of conformal electroplating for surfaces having small features in accordance with the prior art. As shown in FIG. 1A, the substrate 100 has a number of features labeled 105A-105D that may be trenches or vias. Using conformal electroplating may cause holes, as shown in features 105A and 105C, or seams, as shown in features 105B and 105D, to form over the features. This problem is more pronounced for smaller features.

To address the problem of seams and holes in the copper plating, a suppressant and accelerator are added to the electroplating bath to suppress copper plating outside the features (in the field regions 115) while accelerating copper deposition at the bottom of the features. The accelerator allows the copper plating to grow faster from within the features, filling the features from the bottom up to avoid the formation of holes and seams in the copper plating. The accelerator is known as bottom-up superfill or momentum electroplating. However, because the copper plating continues to grow at a faster rate over the features even after filling the features, the “hump” is formed over the features, causing a WID thickness variation. This is known as momentum electroplating. WID is the step height difference between the copper plating area over a feature region and the copper plating area over a field region. FIG. 1B illustrates WID thickness variations in the copper plating due to momentum electroplating in accordance with the prior art. As shown in FIG. 1B, substrate 120 has a number of features labeled 125A-125D that may be trenches or vias. Using momentum electroplating while avoiding holes and seams cause a WID thickness variation 135 over each feature. WID thickness variations typically range from 100-200 nm.

The growth rate of the copper plating is related to the electroplating charge distribution rate. Typically, prior art thin film electroplating schemes include an initial current step and a number of intermediate current steps with gradually increasing current.

FIG. 2 illustrates a typical electroplating current waveform 200 in accordance with the prior art. The initial current step (a specified current level for a specified time) 201 of electroplating current waveform 200 has a relatively low current and is used to fill the smallest features. Larger regions, for which the copper growth rate is equivalent to the field region growth rate, may be only partially filled during the initial current step. Intermediate current steps 202 and 203 are used to fill larger features. After the features are filled, the current is increased at current step 204 to more quickly achieve a specified thickness for the copper plating. Use of a waveform of this general type results in copper protrusions as discussed below.

### BRIEF DESCRIPTION OF THE DRAWINGS

The invention may be best understood by referring to the following description and accompanying drawings that are used to illustrate embodiments of the invention. In the drawings:

FIG. 1A illustrates the drawbacks of conformal electroplating for surfaces having small features in accordance with the prior art;

FIG. 1B illustrates WID thickness variations in the copper plating due to momentum electroplating in accordance with the prior art;

FIG. 2 illustrates a typical electroplating current waveform in accordance with the prior art;

FIG. 3 illustrates a substrate having a copper thin film electroplated on its surface in accordance with one embodiment of the invention;

FIG. 4 illustrates an electroplating current waveform in accordance with one embodiment of the invention; and

FIG. 5 illustrates a process by which a substrate is electroplated in accordance with one embodiment of the invention.

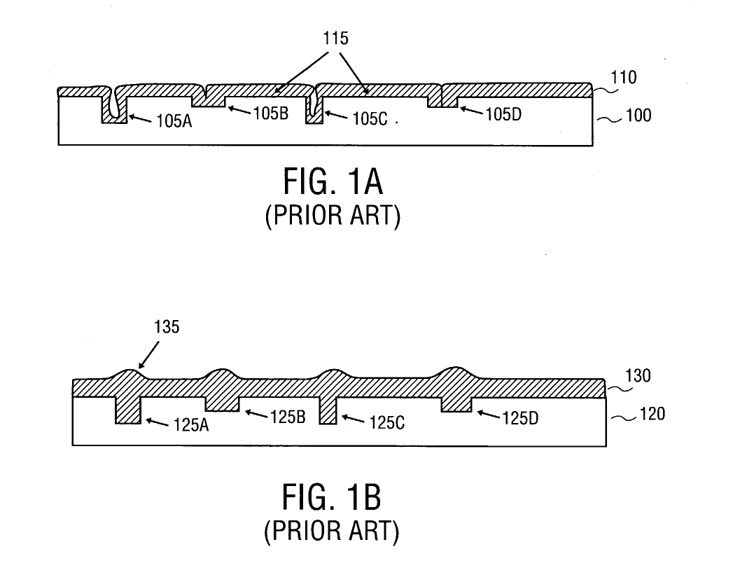

### DETAILED DESCRIPTION

### Overview

Embodiments of the invention provide methods for electroplating a substrate that substantially reduce or eliminate protrusions and decrease WID thickness variations. The number of protrusions formed on the plating surface is highly dependent upon the electroplating current density. Embodiments of the invention vary the electroplating current waveform relative to prior art thin film electroplating schemes in such a way as to substantially reduce or eliminate protrusions. For one embodiment, one or more intermediate current steps of typical art schemes are eliminated and the terminal current step is prolonged.

In the following description, numerous specific details are set forth. However, it is understood that embodiments of the invention may be practiced without these specific details. In other instances, well-known circuits, structures and techniques have not been shown in detail in order not to obscure the understanding of this description.

Reference throughout the specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all features of a single disclosed embodiment. Thus, the claims following the Detailed Description are hereby expressly incorporated into this Detailed Description, with each claim standing on its own as a separate embodiment of this invention.

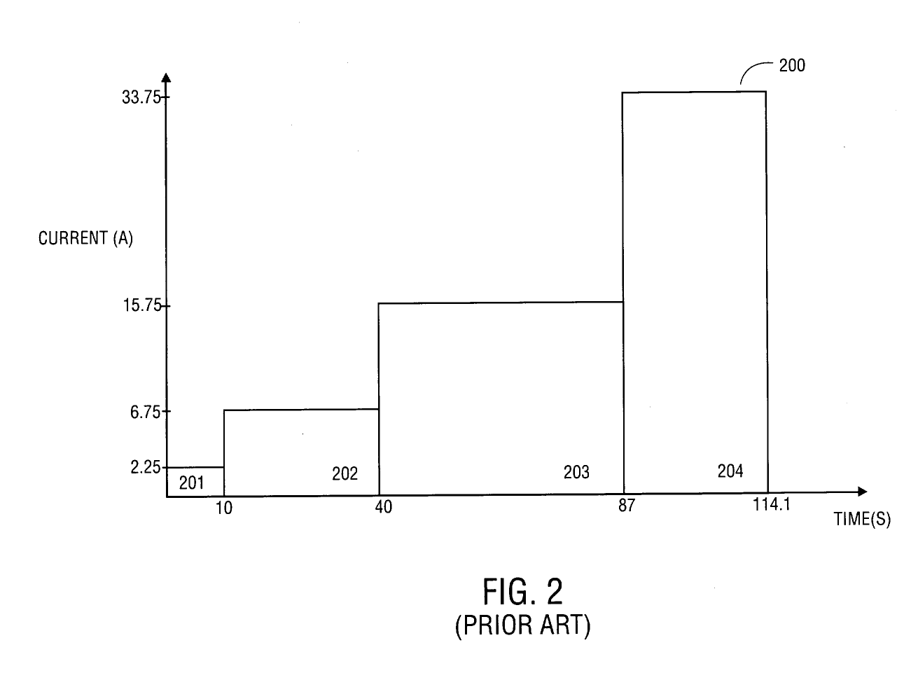

As discussed above in reference to FIG. 2, an initial, relatively low current step is employed to fill the smallest substrate features. The relatively low current is applied long enough to fill the features. The current step used to fill the features is dependent upon the size of the features; smaller features require a lower initial current. The lower current causes the growth of relatively large copper grains on the substrate surface. Moreover, certain grains are particularly oriented to result in high-growth rate. That is, the lower current results in high-growth grains that grow much faster than the neighboring grains, resulting in protrusions.

The grain size of a plated metal film is generally a function of nucleation rate or nuclei density and grain growth rate. If the nucleation rate is much faster and nuclei density is high relative to the growth rate, the final deposit will often have fine grain size. Therefore, eliminating one or more intermediate electroplating current steps of the prior art scheme and using a terminal high current step of longer duration, creates a new nuclei for copper growth on the substrate surface having relatively smaller and randomly-oriented grains. This suppresses the growth of the relative large copper grains resulting from the initial current step and thereby reduces or eliminates protrusions. The increased duration of the terminal current step also substantially decreases WID thickness variation.

The intermediate electroplating current steps of the prior art scheme did not produce copper grains sufficient to suppress the growth of the relatively large grains produced by the initial current step. This is because the intermediate steps produced grains that, although these may not have been large enough to cause protrusions, were not sufficiently small and randomly oriented to suppress the growth of the relatively large grains.

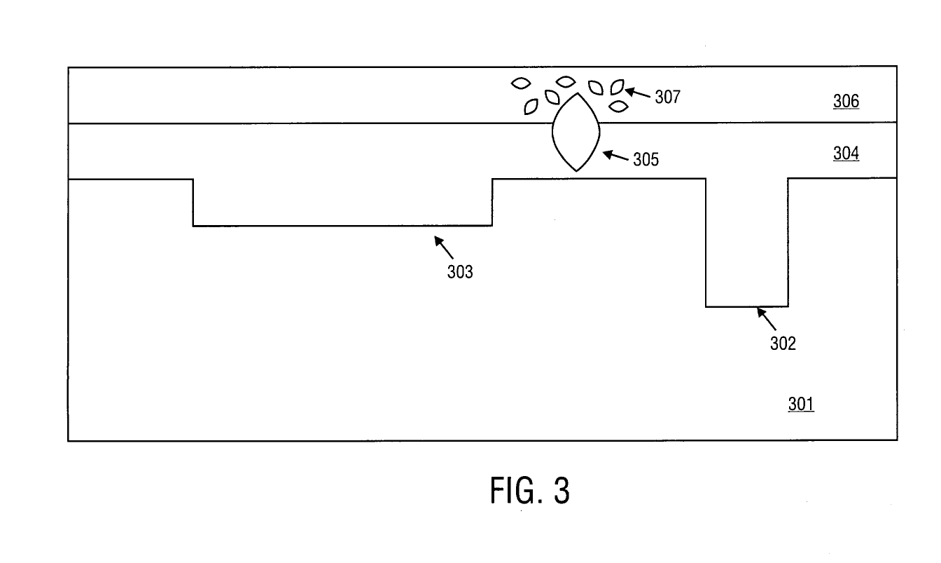

FIG. 3 illustrates a substrate having a copper thin film electroplated on its surface in accordance with one embodiment of the invention. As shown in FIG. 3, substrate 301 has features 302 and 303 formed on its surface. These features (for example, vias or trenches) may have sub-micron dimensions. In accordance with an embodiment of the invention, an initial electroplating current step is selected to fill the features 302 and 303. Electroplating using the selected initial current step results in copper layer 304 having a number of relatively large, high-growth oriented grains, shown for example as grain 305. Eliminating one or more intermediate current steps of the prior art and using a terminal current step of longer duration results in copper layer 306 having relatively small, and more randomly-oriented grains 307. Such electroplating results in a decrease in the number of protrusions and a reduction in WID thickness variation. The copper layers 304 and 306 are not to scale, typically the feature filling current step or steps account for only approximately 10-15 of the total thickness of the copper plating.

### Electroplating Current Waveform

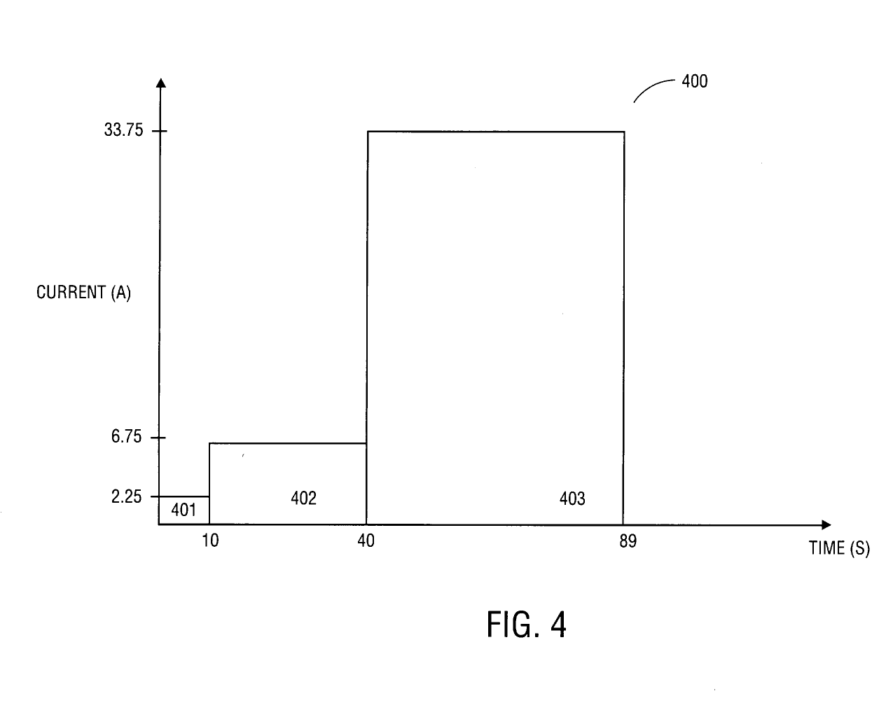

FIG. 4 illustrates an electroplating current waveform in accordance with one embodiment of the invention. The current levels and duration for each current step are exemplary and may be modified in accordance with alternative embodiments of the invention. Electroplating current waveform 400, shown in FIG. 4, includes an initial current step 401 and an intermediate step 402. In accordance with one embodiment of the invention, the current waveform 400 eliminates at least one of the intermediate current steps (i.e., current step 203) and increases the duration of the terminal, high current level, current step. That is, as shown in FIG. 4, the terminal current step has a current level equal to the terminal current step of the prior art, but has an increased duration. As can be discerned by reference to FIG. 4, the electroplating current waveform 400 applies approximately the same total electric charge as the prior art electroplating current waveform 200, thus resulting in a copper plate of approximately the same thickness.

Initial current step 401 has a current level of 2.25 A and a duration of 10 seconds. This is sufficient to fill the smallest features on the substrate, for example, features having a dimension of less than 0.1 microns. As the trend toward smaller feature size continues, the initial current step may vary in current level and duration.

Intermediate current step 402 has a current level of 6.75 A and a duration of 30 seconds. This is sufficient to fill intermediate size features that may not have been filled during the initial current step 401.

The terminal current step 403 has a current level of 33.75 A and a duration of 49 seconds. This is sufficient to suppress the growth of protrusions due to the relatively large, high-growth oriented grains resulting from current steps 401 and 402. The modification of the current level values and/or duration of the initial or intermediate current steps may require the modification of the terminal current step.

### Process

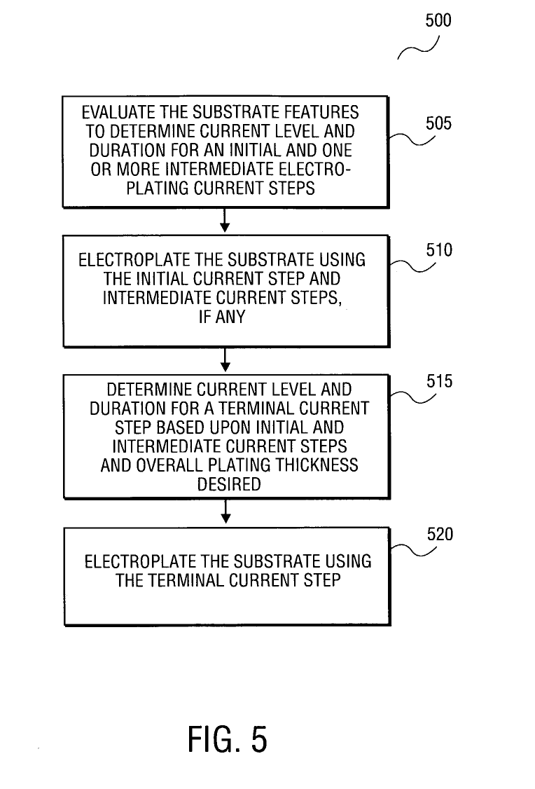

FIG. 5 illustrates a process by which a substrate is electroplated in accordance with one embodiment of the invention. Process 500, shown in FIG. 5, begins with operation 505 in which the substrate features are evaluated. The dimensions of the substrate features determine the current level and the duration of the initial current step. For example, smaller features may require an optimized initial current level. Moreover, the feature dimensions determine not only the current level and duration of an intermediate current step, but also whether an intermediate current step is necessary. For example, if all of the features are within a given dimension range, no intermediate current step may be necessary; that is, the initial current step may be sufficient to fill all of the features of the substrate.

At operation 510 the substrate is electroplated using the initial current step, and intermediate step, if any, determined based upon the dimensions of the feature substrate. This electroplating may result in the formation of relatively large, high-growth oriented grains. Also, low current level of an initial current step in order to fill small features cause increased WID thickness variation.

At operation 515 the terminal current step is determined based upon the initial and intermediate current steps, and upon the specified overall plating thickness. That is, the current level that is sufficient to substantially reduce protrusions is dependent, not only on the relative thickness of the copper layer formed by the initial and intermediate current steps, but also on the specified overall plating thickness. For example, for a 1.0 micron copper film, the current level of the terminal current step has to be higher than approximately 15.75 A, whereas for a 0.5 micron plating the current level of the terminal current step has to be higher than approximately 6.25 A. In general, for various embodiments, a waveform can significantly reduce total protrusion defects regardless of the initial current and total thickness if a characteristic parameter, 1/\overline{L}, defined as

$$\frac{1}{\overline{L}} = \frac{{t}_{gapfill}}{{t}_{overplating}} \frac{1}{{t}_{total}}$$

is less than 0.4; where t_{gapfill} is the thickness plated with the initial and intermediate current steps to fill the features, t_{overplating} is the thickness plated with the terminal current step, and tₜₒₜₐₗ (≦1) is the total thickness of the copper film.

At operation 520 the substrate is electroplated using the terminal current step. The resulting plating has substantially less protrusion defects and substantially reduced WID thickness variations in relation to prior art electroplating schemes.

### General Matters

Embodiments of the invention provide methods for electroplating a substrate that substantially reduce or eliminate protrusions and decrease WID thickness variations.

In reference to FIG. 4, an electroplating current waveform for an embodiment was described that included an intermediate current step sufficient to fill intermediate size features that may not have been filled during the initial current step. In alternative embodiments, for example that do not include intermediate size features, or in which the initial current step is sufficient to fill any such intermediate features, the intermediate current step may be omitted. Further, the terminal current step may be modified in consideration of the initial and intermediate current steps and in consideration of the specified plating thickness. For example, if a thicker plating was specified, the duration of the terminal current step may be increased. Likewise, if the current level of the initial current step was decreased, for example to fill a smaller feature size, then the terminal current step may be modified accordingly.

In reference to FIG. 5, the initial current step is determined so as to fill the substrate features. However, this can lead to increased WID thickness variation. For one embodiment, the terminal current step is determined so as to substantially reduce the resulting WID thickness variations.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

What is claimed is:

1. A method comprising:
forming a plurality of features upon a wafer;
electroplating the wafer with a conductive metal using an initial current step, the initial current step causing the formation of relatively large grains of the conductive metal, the large grains having a high-growth orientation; and
subsequently electroplating the wafer with the conductive metal using a terminal current step that causes the formation of a sufficient amount of relatively small, randomly-oriented grains of the conductive metal such that the formation of protrusions of the conductive metal is reduced.

2. The method of claim 1 wherein subsequently electroplating the wafer with the conductive metal using the terminal current step reduces within die thickness variations.

3. The method of claim 1 wherein the initial current step is not sufficient to fill the plurality of features with the conductive metal, the method further comprising:
electroplating the wafer with the conductive metal using an intermediate current step that is sufficient to fill the plurality of features with the conductive metal.

4. The method of claim 3 wherein the wafer comprises a semiconductor material and the conductive metal is a metal selected from the group consisting essentially of copper, silver, gold and alloys thereof.

5. The method of claim 1 wherein at least one of the plurality of features has a sub-micron dimension and a high aspect ratio.

6. The method of claim 3 wherein a total thickness of the conductive metal electroplated onto the substrate is approximately 1.0 microns.

7. The method of claim 6 wherein the terminal current step has a current level that is higher than approximately 15.75 A.

8. The method of claim 3 wherein a total thickness of the conductive metal electroplated onto the substrate is approximately 0.5 microns.

9. The method of claim 8 wherein the terminal current step has a current level that is higher than approximately 6.25 A.

10. An apparatus comprising:
a substrate having one or more features formed thereon; and
a layer of conductive metal formed on the substrate by electroplating the substrate using an electroplating current waveform having an initial current step that causes the one or more features to be filled with the conductive metal, and a terminal current step that suppresses the formation of protrusions of the conductive metal.

11. The apparatus of claim 10 wherein the substrate is silicon and the conductive metal is a metal selected from the group consisting essentially of copper, silver, gold and alloys thereof.

12. The apparatus of claim 10 wherein at least one of the plurality of features has a sub-micron dimension and a high aspect ratio.

13. The apparatus of claim 10 wherein the initial current step is sufficient to fill the plurality of features with the conductive metal.

14. The apparatus of claim 10 wherein the initial current step is not sufficient to fill the plurality of features with the conductive metal and wherein the electroplating current waveform has an intermediate current step that is sufficient to fill the plurality of features with the conductive metal.

15. The apparatus of claim 14 wherein a total thickness of the conductive metal electroplated onto the substrate is approximately 1.0 micron.

16. The apparatus of claim 15 wherein the terminal current step has a current level that is higher than approximately 15.75 A.

17. The apparatus of claim 14 wherein a total thickness of the conductive metal electroplated onto the substrate is approximately 0.5 microns.

18. The apparatus of claim 17 wherein the terminal current step has a current level that is higher than approximately 6.25 A.

19. The apparatus of claim 10 wherein electroplating the substrates using the terminal current step reduces the within die thickness variation of the layer of conductive metal formed on the substrate.

20. A method comprising:
determining an initial current step of an electroplating current waveform and electroplating a substrate with a conductive metal using the initial current step such that relatively large grains of the conductive metal are formed upon the substrate; and
determining a terminal current step of the electroplating current waveform and subsequently electroplating the substrate with the conductive metal using the terminal current step such that relatively small, randomly-oriented, grains of the conductive metal are formed upon the substrate, the relatively small, randomly-oriented grains suppressing the formation of protrusions of the conductive metal and reducing within die thickness variations.

21. The method of claim 20 wherein the initial current step is not sufficient to fill a plurality of features on the substrate with the conductive metal, the method further comprising:
determining an intermediate current step of an electroplating current waveform and electroplating a substrate with a conductive metal using the intermediate current step such that the plurality of features are filled with the conductive metal.

22. The method of claim 21 wherein the determination of each of the initial current step and the intermediate current step is based upon a dimension of one or more of the plurality of features.

23. The method of claim 22 wherein the determination of the terminal current step is based upon the initial current step, the intermediate current step and a specific total thickness of the conductive metal on the substrate.

24. The method of claim 23 wherein the substrate comprises a semiconductor material and the conductive metal is a metal selected from the group consisting essentially of copper, silver, gold and alloys thereof.

25. The method of claim 23 wherein at least one of the plurality of features has a sub-micron dimension and a high aspect ratio.

26. The method of claim 23 wherein a total thickness of the conductive metal electroplated onto the substrate is approximately 1.0 microns and the terminal current step has a current level that is higher than approximately 15.75 A.

27. An electroplating waveform for electroplating conductive metal film on a substrate comprising;
an initial current step to fill a plurality of features formed within the substrate; and
a terminal current step having a current level and duration that suppresses the formation of protrusions of the conductive metal from the conductive metal film.

28. The electroplating waveform of claim 27 wherein the terminal current step results in a reduction of within die thickness variations.

29. The electroplating waveform of claim 28 wherein the initial current step is insufficient to fill the plurality of features further comprising:
an intermediate current step to fill any of the plurality of features not filled by the initial current step.

30. The electroplating waveform of claim 29 wherein a ratio of a portion of the conductive metal film formed by the initial current step and the intermediate current step to a portion of the conductive metal film formed by the terminal current step, multiplied by a reciprocal of the total thickness of the conductive metal film is less than 0.4.
